(19) United States
(12) Patent Application Publication
(10) Pub. No.: US 2002/0086107 A1
(43) Pub. Date: Jul. 4, 2002

(54) Method of manufacturing consumer stainable wood composite articles

(76) Inventor: David Paxton, Warmsworth (GB)

Correspondence Address: MARSHALL, GERSTEIN & BORUN, 6300 SEARS TOWER, 233 SOUTH WACKER, CHICAGO, IL, 60606-6357, US

(21) Appl. No.: 10/055,195

(22) Filed: Oct. 29, 2001

Related U.S. Application Data
(60) Provisional application No. 60/258,516, filed on Dec. 28, 2000.

(51) Int. Cl. C23C 16/00

(52) U.S. Cl. 427/254

(57) ABSTRACT

Wood composite articles and methods of manufacturing wood composite articles that easily can be stained by a consumer that is inexperienced in staining wood articles, to consistently provide a wood composite article that has a look of natural wood having multiple coats of professionally applied stain. To manufacture a wood composite article that has a relatively lightly colored, unfinished surface that can be consistently stained with a desired color by an inexperienced wood finisher in a very forgiving process, with few steps, it has been found that a loose mat of cellulosic fibers and binder preferably should be first manufactured having a relatively lightly colored, non-fuzzy surface. Further, the pressed article, using at least 40% by weight, preferably 100% by weight, softwood fibers (from a tree that produces a cone), such as pine, redwood or fir, e.g., Southern Pine, should not be post-press heat treated with a tempering oil, such as linseed oil, since after press heat treating with a tempering oil darkens the surface too much to allow for the subsequent application of one or more stain compositions that can be applied easily by an inexperienced consumer. Also, it has been found that one or more coatings of a pigmented wax or pigmented polymeric film-forming agent, can be easily applied to the unfinished wood composite article preferably by first applying one or more base coats from a pigmented, relatively soft wax composition and then from top coat containing a pigmented or non-pigmented harder wax composition, to achieve a professional look that can be consistently applied by the inexperienced wood finisher.

### CROSS-REFERENCE TO RELATED APPLICATION

This application claims priority to U.S. provisional patent application Ser. No. 60/258,516, filed Dec. 28, 2000, which is incorporated herein by this reference in its entirety.

### FIELD OF THE INVENTION

The present invention relates to a wood composite article, and method of manufacturing and surface finishing the article, such as a door, door facing, and other wood composite articles having a smooth or embossed wood grain pattern, that can be stained easily by an untrained consumer with a plurality of wax coating materials to seal the surface of the wood composite articles having a smooth or embossed wood grain pattern, that can be stained easily by an untrained consumer with a plurality of wax coating materials to seal the surface of the wood composite articles with a pigmented wax film and provide a darkened wood grain pattern. More particularly, the present invention is directed to a wood composite article that is left unfinished (unstained) and not primed or linseed oil treated after pressing so that the article easily accepts color from a wax carrier containing a colored pigment so that the wood composite article can be surface finished with the pigmented waxes, by an untrained consumer, to a desired color, to look like a professionally finished natural wood.

### BACKGROUND OF THE INVENTION

Wood composite doorskins pressed from a loosely formed mat containing a combination of cellulosic fibers and a natural or synthetic thermosetting resin binder, such as a urea formaldehyde, melamine formaldehyde, and/ or phenol formaldehyde resin, have been manufactured for years. The doorskins are made by compressing a mat of fibrillated cellulosic fibers and a binder capable of adhering the fibers together, to compress a 1 to 3 inch mat down to a ⅛ inch to ¼ inch thick doorskin, while providing embossed, aesthetically pleasing molded surface contours, such as a six panel door, and a smooth or wood grain texture in all exterior, visible surfaces. When the doorskin emerges from the heated press, the surface is soft and has a fuzzy fibrous surface with surface fiber ends extending upwardly from the surface. Soft surfaces are particularly undesirable because it is difficult to paint soft surfaces or apply other finishing components (e.g., water-resistant sealers) to soft surfaces. Furthermore, the integrity, surface smoothness, and aesthetic characteristics of the board product or molded product, either grained or smooth, are compromised by the soft surfaces. The soft fuzzy surface is then post press treated with a tempering oil, such as linseed oil, to cause the surface fibers to lay down and conform to the door skin surface shape. The pressed article also has a relatively darkly colored surface, so that to achieve a color that looks like a natural wood surface on the planar uppermost surface of the article, the surface is sprayed with a white water-based paint (primer), so that any embedded wood ticking can be seen, but the planar, white upper surface must be completely changed in color to approximate the color of natural wood. Therefore, the surface of the door is painted with multiple layers of lacquer, or varnish, to provide the look of a natural wood surface.

The wood composite articles and methods of manufacturing the articles of the present invention differ from the above-described articles primarily by providing a relatively lightly colored, unprimed, unstained and unfinished wood composite article without a soft, fuzzy surface, that can be consistently finished and stained by the untrained consumer to a desired color with the look of a professionally finished natural wood article. Also, because of the process of manufacture, the wood composite articles of the present invention, after finishing and staining, later can be re-stained over their entire surface to change and/or darken the surface color; or damaged, e.g., scratched, surface portions can be again stained to match the initial finish and color.

### SUMMARY OF THE INVENTION

In brief, the present invention is directed to wood composite articles and methods of manufacturing wood composite articles that easily can be stained by a consumer that is inexperienced in staining wood articles, to consistently provide a wood composite article that has a look of natural wood having multiple coats of professionally applied stain. To manufacture a wood composite article that has a relatively lightly colored, unfinished surface that can be consistently stained with a desired color by an inexperienced wood finisher in a very forgiving process, with few steps, it has been found that a loose mat of cellulosic fibers and binder preferably should be first manufactured having a relatively lightly colored, non-fuzzy surface. Further, the pressed article, using at least 40% by weight, preferably 100% by weight, softwood fibers (from a tree that produces a cone), such as pine, or fir, e.g., Southern Pine, should not be post-press heat treated with a tempering oil, such as linseed oil, since after press heat treating with a tempering oil darkens the surface too much to allow for the subsequent application of one or more stain compositions that can be applied easily by an inexperienced consumer. Also, it has been found that one or more coatings of a pigmented wax or pigmented polymeric film-forming agent, can be easily applied to the unfinished wood composite article preferably by first applying one or more base coats from a pigmented, relatively soft wax composition and then from top coat containing a pigmented or non-pigmented harder wax composition, to achieve a professional look that can be consistently applied by the inexperienced wood finisher.

Accordingly, one aspect of the present invention is to provide a method of manufacturing a lightly colored, unfinished wood composite article that has a hard, non-fuzzy surface, and a method of finishing an outer surface of the wood composite article with a pigmented wax or pigmented polymeric film-forming material-containing stain composition.

Another aspect of the present invention is to provide a method of manufacturing a relatively lightly colored unfinished wood composite article containing am embossed wood grain pattern it its intended visible surface, selling the unfinished wood composite article to a consumer, and providing the consumer a selection of differently colored finishing compositions that be applied consistently and easily over the embossed surface to darken the embossed grain pattern to a greater extent than coloration achieved in the upper surface of the wood composite article, thereby achieving a look of professionally finished natural wood.

Another aspect of the present invention is to provide a method of making a lightly colored unfinished wood composite article having a hard, non-fuzzy surface and providing a consumer with a selection of differently colored stain compositions, said stain compositions being especially adapted for finishing the unfinished wood composite article, in a consumer-selected and consumer-applied color, wherein the stain compositions include a wax or polymeric film-forming carrier and a dye or pigment, preferably a pigment.

Still another aspect of the present invention is to provide a set of at least two stain compositions that are especially adapted for house finishing of a lightly colored, unfinished wood composite article, wherein the stain compositions include (a) a base coat composition comprising a wax and a pigment that is applied in one to five applications, preferably two to three applications; and (b) a top coat composition comprising a harder wax than the wax of the base coat composition, said top coat composition optionally containing a pigment, applied over the base coat composition in one or multiple applications.

The above and other aspects of the present invention will become more apparent from the following detailed description of the preferred embodiment, taken in conjunction with the drawing.

### BRIEF DESCRIPTION OF THE DRAWING

FIG. 1 is a front view of an embossed, lightly colored wood composite door skin that is unfinished; and

FIG. 2 is an enlarged, side view of an embossed, preferred wood grain line simulating a pine wood grain.

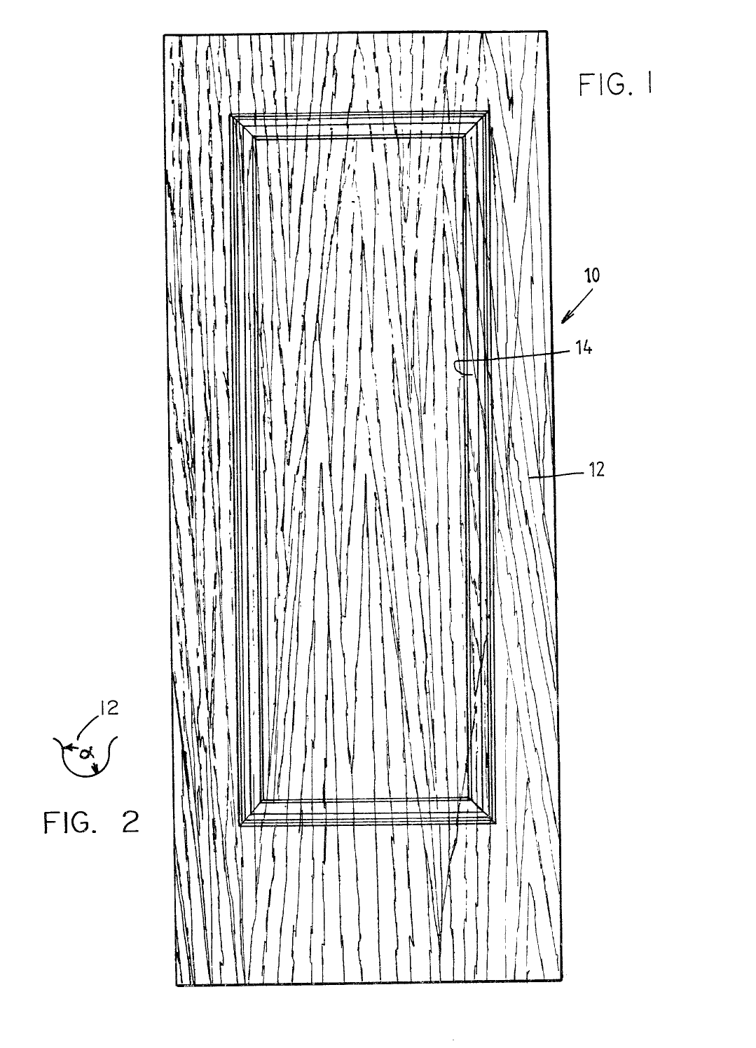

### DETAILED DESCRIPTION OF THE PREFERRED EMBODIMENT

According to the invention, a method of making a lightly colored, wood composite article, having a non-fuzzy surface, is provided for subsequent staining. The preferred method of making the lightly colored composite article includes the steps of combining a fibrous material with a binder resin and a sizing agent to form a mixture. The preferred method further includes the step of drying the mixture to a moisture content of about 6 percent by weight (wt. %) to about 14 wt. % based on the weight of the fibrous material to form a mat, and thereafter coating a surface of the mat with about 3 grams per square meter (g/m²) to about 50 g/m² of an aqueous solution containing a thermosetting binder resin. The preferred aqueous solution also includes a wetting agent, a mold release agent, and a set retarder. Once coated with the aqueous solution, the mat is consolidated under heat and pressure to form the composite article that can be easily finished with a base coat of a pigmented wax or pigmented polymeric film-forming coating material by the inexperienced consumer.

According to a preferred embodiment of the invention, a method of making a molded composite article includes the steps of blending a cellulosic material with water in a steam-pressurized vessel to form fibrillated cellulosic fibers, and passing the cellulosic fibers through a discharge conduit of the vessel and into a blowline wherein the cellulosic fibers are combined with a binder resin (i.e., a thermosetting resin) and a sizing agent to form a mixture. Thereafter, the mixture is dried to a moisture content of about 6 wt. % to about 14 wt. % based on the weight of the fibrous material. The dried mixture is deposited onto a water-pervious support member to form a mat. The method further includes the step of coating a surface of the dried mat with about 3 g/m² to about 50 g/m² of an aqueous solution containing a thermosetting binder resin, such as an amino resin, urea formaldehyde resin, melamine formaldehyde resin, or a mixture thereof. Optionally, the aqueous solution includes one or more of a wetting agent, a mold release agent, and a set retarder. Once coated with the aqueous solution, the coated mat is consolidated under heat and pressure to form the molded composite article.

The cellulosic material typically has a moisture content of about 30 wt. % to about 60 wt. % based on the dry weight of the cellulosic material. Suitable cellulosic material for use in accordance with the invention generally includes lignocellulosic fibers and lignocellulosic biomass. The lignocellulosic fibers primarily include wood fibers formed by fiberization of soft woody chip material, but are not limited solely to such wood fibers. Lignocellulosic biomass includes lignocellulose derived from biomass sources such as, for example, trees, plants, and other vegetation, agricultural products and wastes (e.g., corn, fruit, garbage ensilage, etc.), algae and other marine plants.

The cellulosic material is combined with water in a vessel, preferably a pressurized vessel, and more preferably a steam-pressurized refiner known in the art as being suitable for preparing fibrillated fibers. A preferred weight ratio of water combined with the cellulosic material is about 1 to 1. A more preferable weight ratio of water to cellulosic material, however, is about 0.8 to 1. Within the vessel, the cellulosic material is exposed to heat and saturated steam having a pressure of about four bars to about eight bars, preferably about five bars to about seven bars. A suitable residence time for the cellulosic material within the vessel is about two minutes to about eight minutes, preferably about three minutes to about five minutes. The temperature of this fiberization process step within the steam-pressurized refiner is set by the specified saturated steam pressure.

The vessel includes a discharge conduit through which the formed fibrillated fibers exit. As the fibrillated fibers exit the vessel it is combined with the binder resin and a sizing agent before the combined mixture is deposited onto a water-pervious support member. This combination occurs through known techniques referred to in the art as “blowline blending.” The binder resin is added to bind the fibrillated fibers, and the setting agent is added to impart water repellency to the finished consolidated article.

An amino resin, a urea formaldehyde resin, a melamine formaldehyde resin, or a combination thereof, may be used as the binder resin, however, a urea formaldehyde resin or a mixture of a urea formaldehyde and a melamine formaldehyde resin is preferred. Generally, the amount of the binder resin that is blended with the fibrillated fibers is about 2 wt. % to about 15 wt. % based on the dry weight of the fibers. Where the binder resin is an amino resin, the amount of resin that is blended with the fibers is about 7 wt. % to about 15 wt. % based on the dry weight of the fibers, preferably about 8 wt. % to about 10 wt. %. Where the binder resin is a urea formaldehyde resin and/or a melamine formaldehyde resin, the amount of resin that is blended with the fibers is about 2 wt. % to about 6 wt. % based on the dry weight of the fibers, preferably about 3 wt. % to about 4 wt. %.

Any sizing agent known in the art may be blended with the fibers, however, a solid or emulsion-type petrochemical-based sizing agent is preferred, such as Mobil M75 which is available from Mobil Oil Corporation. Preferably, the amount of sizing agent that is blended with the fibrillated fibers is about 1 wt. % to about 3 wt. % based on the weight of the fibrous material. The amount of the sizing agent will vary within the aforementioned range based on the type of article being manufactured. For example, if an exterior article is being made, the amount of the sizing agent should be higher than if an interior article were being made.

As noted above, the resin- and sizing agent-containing fibrillated fibers is dried to a moisture content of about 6 wt. % to about 14 wt. % before or after it is deposited onto a water-pervious support member, such as a fine screen or a Fourdrinier wire, to form a mat having a moisture content of about 6 wt. % to about 14 wt. %, and preferably about 9 wt. % to about 11 wt. % based on the weight of the fibers.

A moisture content in excess of that suggested for a dry process and less than that suggested for a wet-dry process, in combination with the pre-press resin spray or coating step, described below, provides significant advantages. It is believed that too little moisture (i.e., less than about 6 wt. %) will cause the mat to prematurely cure, whereas too much moisture (i.e., more than about 14 wt. %) will result in a molded composite article exhibiting severe delamination and poor bonding of fibrous materials. The presence of about 6 wt. % to about 14 wt. % moisture in the fibers of the mat, and the subsequent coating of the mat surface(s) with a thermosetting binder resin, results in a mat which, when pressed, does not prematurely cure and does not suffer from delamination or display poor fiber bonding.

In accordance with the invention, at least one surface (and preferably both top and bottom surfaces) of the fibrillated fiber and binder combination, having a moisture content of about 6 wt. % to about 14 wt. %, is (are) coated with a thermosetting resin and, optionally, various additives, prior to the consolidation step. It is preferred to apply an aqueous solution of additives in addition to the resin binder, including: a wetting agent; a mold release agent; and a set retarder. Generally, any wetting agent, mold release agent, and set retarder known in the art are suitable for use in accordance with the invention. Preferably, however, the wetting agent is a combination of an anionic and a non-ionic surfactant, the mold release agent is a combination of an anionic and a non-ionic surfactant, and the set retarder is also a combination of an anionic and a non-ionic surfactant. One material that acts as a combined wetting agent/mold release agent/set retarder is commercially-available under the product name Wurtz 529S from the Peter Wurtz Company of Switzerland. Binder (i.e., thermosetting) resins suitable for use in the aqueous solution can be identical to those used during the blowline blending step. However, the binder resin need not be identical to those used during the blowline blending step, and phenol formaldehyde resin should only be used if a darker surface finish is acceptable.

A preferred aqueous solution for use in accordance with the invention is made up of about 0.15 wt. % to about 10 wt. % of the wetting agent, about 0.15 wt. % to about 10 wt. % of the mold release agent, about 0.15 wt. % to about 10 wt. % of the set retarder, and about 1 wt. % to about 30 wt. % of the thermosetting resin, preferably a urea formaldehyde resin, a melamine formaldehyde resin or a mixture thereof, the balance being water. A more preferred aqueous solution for use in accordance with the invention, however, is made up of about 0.25 wt. % to about 3 wt. % of the wetting agent, about 0.25 wt. % to about 3 wt. % of the mold release agent, about 0.25 wt. % to about 3 wt. % of the set retarder, and about 10 wt. % to about 15 wt. % of the thermosetting resin, the balance being water. The amount of the aqueous solution added to the fibrous material is in a range of about 3 g/m² (g/m²) to about 50 g/m², preferably about 20 g/m² to about 35 g/m², and more preferably about 25 g/m² to about 30 g/m². The amount of the aqueous solution added to the fibrous material is dependent upon the amount of resin present in the solution. For example, if there is a high concentration of the thermosetting resin in the solution, lower amounts of the solution will need to be sprayed or coated onto the board surface(s) to achieve the desired results. Conversely, if there is a low concentration of the thermosetting resin in the solution, higher amounts of the solution will need to be sprayed or coated onto the board surface(s) to achieve the desired concentration of binder at the surface of the mat being hot pressed.

After the fibrous mat has been coated with the resin binder, the mat is placed in a suitable pressing apparatus and consolidated under heat and pressure to form the molded composite article. The pressing apparatus preferably has press platens operating at a temperature in a range of about 130° C. to about 230° C., preferably about 130° C. to about 190° C., more preferably about 155° C. to about 175° C. Press times generally are relatively short, and are preferably in a range of about 15 seconds to about 35 seconds. These consolidation parameters, however, are variable depending upon the materials and apparatus being used. As will be apparent to those of ordinary skill in the art, desirable pressing temperatures vary according to various factors, including, but not limited to, the following: the thickness of the board, the type of cellulosic material being pressed; the moisture content of the cellulosic material, the press time, and the specific thermosetting resin which is used.

After the consolidation step, the formed molded composite article is removed from the press and cooled to ambient temperature. Because the molded composite article has superior surface quality (not soft, not fuzzy) without any further treatment, the need for: (a) tempering the formed article with oils; (b) post-press sealers; and/or (c) surface sanding operations to remove loose fibers, is either greatly reduced or altogether eliminated. Hence, after the article has been formed in the press and cooled, it may be immediately stained or, in accordance with an important embodiment of the present invention, may be sold unfinished for later staining by a consumer untrained and inexperienced in wood finishing.

The inventive method enables the manufacture of a molded composite article having very hard, relatively light-colored surfaces that readily accept pigments from a wax and/or polymeric film-forming carrier, enabling the consumer to finish the surface to achieve a wood composite article having a professionally finished look of a natural wood article in any desired color. The composite articles do not require conventional post-pressing treatment (e.g., tempering, post-press surface sanding, and/or post-press application of sealers) in order to produce a surface free of loose fiber and acceptable for subsequent staining, described in more detail hereinafter.

Wax Or Polymeric Film-Forming Component—Based Stains

The unfinished wood composite articles, after surface treatment with a thermosetting binder and then hot pressing, as described, then is ready to be finished (stained) by coating with a pigmented wax or polymeric film-forming composition containing a dye or pigment, as well known in the art for finishing natural wood products, e.g., natural doors, furniture, and the like.

The film-forming material can be a natural wax, such as beeswax and/or spermaceti; a vegetable wax, such as carnauba, candelillia, Japan wax, ouricury wax, rice-bran wax, jojoba oil, castor wax and/or bayberry wax; a mineral wax, such as montan wax, peat wax, ozokerite wax and/or ceresin wax; a petroleum wax, such as paraffin wax, and/or microcrystalline wax; a synthetic wax such as a polyethylene wax; polymethylene wax, and/or Fischer-Tropsch wax, a chemically modified wax, such as an air-oxidized wax, a wax reacted with a polycarboxylic acid, e.g., a maleic, an acrylic wax, or a substituted amide wax; a silicone; or synthetic waxes and polymeric materials having wax-like properties, such as a C₂₀+∝-olefin.

Base stain compositions useful as a first coating in surface finishing the above-described, unfinished wood composite articles of the present invention generally include about 60-90% by weight of a natural or synthetic wax, or other polymeric film-forming material having wax-like properties, and about 10-40% by weight additives, including solvents (organic and/or water), dye(s), pigment(s), emulsifying agents, plasticizers, emulsion stabilizing agents, leveling agents and/or any other additives commonly found in stains and floor polishes, generally in the form of an emulsion. Pigment and/or dye content generally is in the range of about 0.1% to about 20%, preferably about 1% to 10%, more preferably about 1% to 5% by weight of the stain composition.

The preferred base stain compositions have a creamy, shoe-polish consistency and contain about 70-90% by weight of one or more natural or vegetable waxes and 1-10% by weight of one or more pigments having a desired color, in an aqueous emulsion, with or without organic solvents, preferably having less than 10% volatile organic content (VOC). An example is RONSEAL BRUSHING WAX, Ronseal Limited, Thorncliffe Park, Chapeltown, Sheffield S35 ZYP, United Kingdom, that is an aqueous emulsion of a natural wax that has a creamy consistency and includes one or more light-fast pigments to provide a desired surface color to the unfinished wood composite articles of the present invention, and a darker colored embossed wood grain pattern. The base wax/polymeric film-forming and coloring stain composition is applied liberally over the surface of the unfinished wood composite article, in a thick coat, preferably with a brush, and excess stain composition is left in contact with the surface of the wood composite article for at least 5 minutes, preferably 10-20 minutes, before buffing with a soft cloth or steel wool along the embossed grain pattern, to remove excess wax and/or polymeric film.

To achieve the full advantage of the present invention, the unfinished wood composite article 10 of the present invention is embossed with elongated wood grain lines 12 in a wood grain pattern, such as pine, as shown in the drawing, and optionally contains one or more embossed panels 14. Any embossed tick profile will hold some pigment for darker coloration of the wood grain pattern, however, to achieve the full advantage of the present invention, the wood grain pattern is embossed in an elongated profile that has an angle of 70-100° between a bottom surface 16 and side surfaces 18 of the embossed wood grain lines 12, as shown in FIG. 2. One or more additional coats of the base coat of wax/polymeric film-forming stain composition can be applied after the first base coat has been buffed with a soft cloth.

To achieve a good sheen on the finished wood composite article of the present invention, one or more top coats of a wax composition, having a harder wax than the base stain composition, with or without pigment, can be applied over the above-described base coat(s) of pigmented wax. Preferred top coat materials are, for example, a synthetic acrylic wax, containing no pigment, called Acrylic Wax, by Polyvine Limited, Vine House, Rockhampton, Berkeley, Glos. GL13 9DT, United Kingdom; or a beeswax based product by RONSEAL, called COLRON Antiquing Wax, containing one or multiple colors of pigment, intended as a top coat over the RONSEAL BRUSHING WAX, described earlier for use on natural wood products. The wax/polymer based film-forming top coating materials also contain 60-90% by weight natural or synthetic wax or other polymeric film-forming materials having wax-like properties, and about 10-40% by weight solvents and/or water, dye(s), pigment(s), emulsifying agents, plasticizers, emulsion stabilizing agents, leveling agent(s), and any other additives commonly found in stains and floor polishes. The optional top coating material can contain up to 20% pigment and/or dye and preferably is in a shoe polish consistency for application with a soft cloth. The top coat(s) are allowed to dry for one to two hours before buffing with a soft cloth or buffing apparatus to remove excess top coat film-forming material.

The foregoing description is given for clearness of understanding only, and no unnecessary limitations should be understood therefrom, as modifications within the scope of the invention may be apparent to those skilled in the art.

What is claimed is:

1. A method of manufacturing a wood composite article comprising embossing a wood grain pattern into a mat under sufficient heat and pressure to provide a wood composite article having structural integrity, said mat comprising cellulosic fibers and a binder capable of adhering the fibers together, including the step of contacting a surface of the mat with a thermosetting resin binder in an amount sufficient to provide a smooth, non-fuzzy, wood grain-embossed upper surface after embossing, such that no tempering oil post-press heat treatment step is performed on the embossed surface and, thereafter, applying to said embossed surface a base coating of a dye- or pigment-containing composition containing a wax or polymeric film-forming carrier to darken the embossed wood grain pattern and apply a wax or polymeric film over the embossed surface to simulate a natural wood finish.

2. A method in accordance with claim 1, wherein the unfinished wood composite article is sold to a consumer, for application of the film-forming composition by the consumer.

3. A method in accordance with claim 1, wherein the surface of the mat is contacted with an aqueous solution of the thermosetting resin binder in an amount of about 3 g/m² to about 50 g/m², said aqueous solution further including a wetting agent, a mold-release agent, and a resin set retarder.

4. A method in accordance with claim 1, wherein the mat has a moisture content of about 6 wt. % to about 14 wt. %, based on the dry weight of the fibers in the mat, prior to contacting the surface of the mat with the thermosetting resin binder.

5. A method in accordance with claim 4, wherein the mat has a moisture content of about 9 wt. % to about 11 wt. %, based on the dry weight of the fibers in the mat, prior to contacting the surface of the mat with the thermosetting resin binder.

6. A method in accordance with claim 3, wherein the aqueous solution comprises:
(i) about 0.15 wt. % to about 10 wt. % of a wetting agent, based on the total weight of the solution;
(ii) about 0.15 wt. % to about 10 wt. % of a mold release agent, based on the total weight of the solution;
(iii) about 0.15 wt. % to about 10 wt. % of a set retarder, based on the total weight of the solution; and
(iv) about 2 wt. % to about 30 wt. % of a thermosetting resin, based on the total weight of the solution.

7. A method in accordance with claim 6, wherein the aqueous solution comprises:
(i) about 0.25 wt. % to about 3 wt. % of a wetting agent, based on the total weight of the solution;
(ii) about 0.25 wt. % to about 3 wt. % of a mold release agent, based on the total weight of the solution;
(iii) about 0.25 wt. % to about 3 wt. % of a set retarder, based on the total weight of the solution; and
(iv) about 2 wt. % to about 10 wt. % of a thermosetting resin, based on the total weight of the solution;

8. A method in accordance with claim 3, wherein the surface of the mat is contacted with the aqueous thermosetting resin solution in an amount of about 20 g/m² to about 35 g/m².

9. A method in accordance with claim 3, wherein the mat is embossed at a press temperature of about 130° C. to about 180° C. for a press time period of about 15 seconds to about 35 seconds.

10. A method in accordance with claim 9, wherein the mat is embossed at a press temperature of about 155° C. to about 175° C. for a press time period of about 15 seconds to about 35 seconds.

11. A method in accordance with claim 1, wherein the carrier for the base coating composition comprises a wax.

12. A method in accordance with claim 11, wherein the wax is a natural wax.

13. A method in accordance with claim 12, wherein the natural wax is beeswax.

14. A method in accordance with claim 11, wherein the wax is a vegetable wax.

15. A method in accordance with claim 14, wherein the vegetable wax is selected from the group consisting of carnauba, rice-bran, jojoba, castor, and bayberry.

16. A method in accordance with claim 11, wherein the wax is a mineral wax.

17. A method in accordance with claim 16, wherein the mineral wax is selected from the group consisting of montan, peat, ozokerite, and ceresin.

18. A method in accordance with claim 11, wherein the wax is a petroleum wax.

19. A method in accordance with claim 18, wherein the petroleum wax is selected from the group consisting of paraffin, and microcrystalline.

20. A method in accordance with claim 11, wherein the wax is a synthetic wax.

21. A method in accordance with claim 11, wherein the synthetic wax is an acrylic wax.

22. A method in accordance with claim 1, wherein the base coat composition includes 0.1% to 20% by weight of a pigment.

23. A method in accordance with claim 22, wherein the base coat composition includes 0.1% to 10% by weight of a pigment.

24. A method in accordance with claim 23, wherein the base coat composition contains 60-90% by weight of the film forming carrier.

25. A method in accordance with claim 1, further including the step of applying a top coat of a film-forming composition over one or more layers of the base coat composition, said top coat composition comprising a wax or polymeric film-forming carrier that is harder than the wax or polymeric film-forming carrier in the base coat composition.

26. A method in accordance with claim 25, wherein the top coat composition includes 0.1% to 20% by weight of a colored pigment.

27. A method in accordance with claim 26, wherein a colored pigment in the top coat composition is the same, or different from a colored pigment in the base coat composition.

28. A method in accordance with claim 25, wherein the base coat composition is applied to the unfinished, non-tempered wood composite article by brush application, followed by buffing after at least five minutes of base-coat contact.

29. A method in accordance with claim 28, wherein the top coat composition is applied with a soft cloth and subsequent buffing before the top coat has completely dried.

30. A method in accordance with claim 29, wherein the base coat composition comprises a natural wax carrier and the top coat comprises an acrylic wax carrier.
